(19) United States
(12) Patent Application Publication
(10) Pub. No.: US 2025/0287823 A1
(43) Pub. Date: Sep. 11, 2025

(54) DISPLAY MODULE AND DISPLAY APPARATUS

(71) Applicants: Hubei Yangtze Industrial Innovation Center Of Advanced Display Co., Ltd., Wuhan (CN); Wuhan Tianma Microelectronics Co., Ltd., Wuhan (CN)

(72) Inventors: Dandan ZANG, Wuhan (CN); Yu CAI, Wuhan (CN)

(73) Assignees: Hubei Yangtze Industrial Innovation Center Of Advanced Display Co., Ltd., Wuhan (CN); Wuhan Tianma Microelectronics Co., Ltd., Wuhan (CN)

(21) Appl. No.: 19/218,909

(22) Filed: May 27, 2025

(30) Foreign Application Priority Data
Jan. 17, 2025 (CN) 202510080866.6

(51) Int. Cl. H10K 59/80; H10K 39/34; H10K 59/122

(52) U.S. Cl. CPC H10K 59/8792; H10K 39/34; H10K 59/122

(57) ABSTRACT

Provided are a display module and a display apparatus. The display module includes a display panel and a first optical sensor. The display panel includes a first display region and a second display region, and a light transmittance of the first display region is greater than or equal to a light transmittance of the second display region. Both the first display region and the second display region comprise a substrate, light-emitting units, and light transmitting holes, and the light-emitting units and light transmitting holes are located on a same side of the substrate. Along a direction perpendicular to a plane of the substrate, the first optical sensor at least partially overlaps with the first display region, the first optical sensor does not overlap with the second display region, and the light-emitting units do not overlap with the light transmitting holes.

### CROSS-REFERENCE TO RELATED APPLICATION

The present application claims priority to Chinese Patent Application No. 202510080866.6, filed on Jan. 17, 2025, the content of which is incorporated herein by reference in its entirety.

### TECHNICAL FIELD

The present disclosure relates to the field of display technology, and in particular, to a display module and a display apparatus.

### BACKGROUND

With the continuous advancement of science and technology, more and more electronic devices with display functions are widely used in people's daily life and work, bringing great convenience to people's daily life and work, and becoming indispensable and important tools for people today.

Organic Light Emitting Diode (OLED) display devices have been widely used in many display fields due to their high brightness, high luminous efficiency, high contrast ratio, ultra-wide viewing angle, low power consumption and other characteristics. With the continuous development of display technology, display panels equipped with optical sensors have emerged. Currently, the display panels equipped with optical sensors have the problem of inconsistent visual effects between different regions of the display panels in a screen-off state.

### SUMMARY

In view of the above, the present disclosure provides a display module and a display apparatus for reducing a difference in reflectance between a first display region and a second display region while improving a light transmittance of the first display region of the display panel.

In a first aspect, the present disclosure provides a display module including a display panel and a first optical sensor;
where the display panel comprises a first display region and a second display region, and a light transmittance of the first display region is greater than or equal to a light transmittance of the second display region; and
where both the first display region and the second display region comprise a substrate, light-emitting units, and light transmitting holes, and the light-emitting units and the light transmitting holes are located on a same side of the substrate; and along a direction perpendicular to a plane of the substrate, the first optical sensor at least partially overlaps with the first display region, the first optical sensor does not overlap with the second display region, and the light-emitting units do not overlap with the light transmitting holes.

In a second aspect, the present disclosure provides a display apparatus including the above-mentioned display module.

### BRIEF DESCRIPTION OF DRAWINGS

In order to better illustrate the technical solutions of embodiments of the present disclosure, the drawings required to be used in the embodiments will be briefly introduced below. Apparently, the drawings in the following description are merely some embodiments of the present disclosure, and those of ordinary skill in the art can obtain other drawings from these drawings without any creative efforts.

FIG. 1 is a schematic top view of a display module provided by an embodiment of the present disclosure;

FIG. 2 is an enlarged schematic view of a region A01 in FIG. 1 according to an embodiment of the present disclosure;

FIG. 3 is a schematic cross-sectional view of a display module provided by an embodiment of the present disclosure;

FIG. 4 is a schematic top view of another display module provided by an embodiment of the present disclosure;

FIG. 5 is an enlarged schematic view of a region A02 in FIG. 4 according to an embodiment of the present disclosure;

FIG. 6 is a schematic cross-sectional view of a second display region and a third display region of a display module provided by an embodiment of the present disclosure;

FIG. 7 is a schematic top view of a third-color color filter layer (CF) located in a second display region provided by an embodiment of the present disclosure;

FIG. 8 is a schematic top view of a first-color color filter layer located in the second display region provided by an embodiment of the present disclosure;

FIG. 9 is a schematic cross-sectional view of yet another display panel provided by an embodiment of the present disclosure;

FIG. 10 is a schematic top view of a pixel definition layer in the region A01 in FIG. 1 according to an embodiment of the present disclosure;

FIG. 11 is a schematic top view of a light-shielding layer in the region A01 in FIG. 1 according to an embodiment of the present disclosure;

FIG. 12 is a schematic cross-sectional view of a first display region and a second display region of another display module provided by an embodiment of the present disclosure;

FIG. 13 is a schematic cross-sectional view of a first display region and a second display region of yet another display module provided by an embodiment of the present disclosure;

FIG. 14 is a schematic cross-sectional view of a first display region and a second display region of yet another display module provided by an embodiment of the present disclosure;

FIG. 15 is another enlarged schematic view of the region A01 in FIG. 1 according to an embodiment of the present disclosure; and

FIG. 16 is a schematic view of a display apparatus provided by an embodiment of the present disclosure.

### DESCRIPTION OF EMBODIMENTS

In order to better understand the technical solutions of the present disclosure, embodiments of the present disclosure are described in detail below in conjunction with the drawings.

It should be clear that the embodiments described are only some rather than all of the embodiments of the present disclosure. Based on the embodiments of the present disclosure, all other embodiments obtained by those ordinary skilled in the art without creative efforts shall fall within the protection scope of the present disclosure.

The terms used in the embodiments of the present disclosure are only for the purpose of describing specific embodiments, and are not intended to limit the present disclosure. The singular forms “a/an”, “said”, and “the” used in the embodiments of the present disclosure and the attached claims are also intended to include plural forms, unless the context clearly dictates otherwise.

It should be understood that the term “and/or” used herein is only used to describe the association relationship of associated objects, representing that there can be three relationships. For example, A and/or B can represent: A exists alone, A and B exist at the same time, and B exists alone. In addition, the character “/” herein generally represents that the associated objects before and after it are in an “or” relationship.

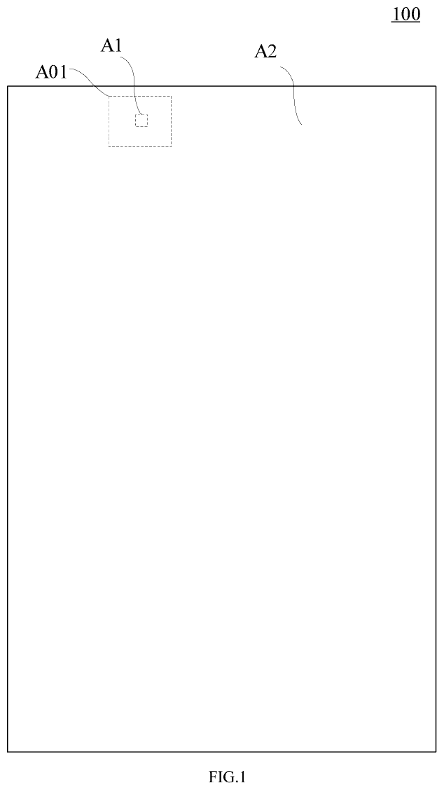

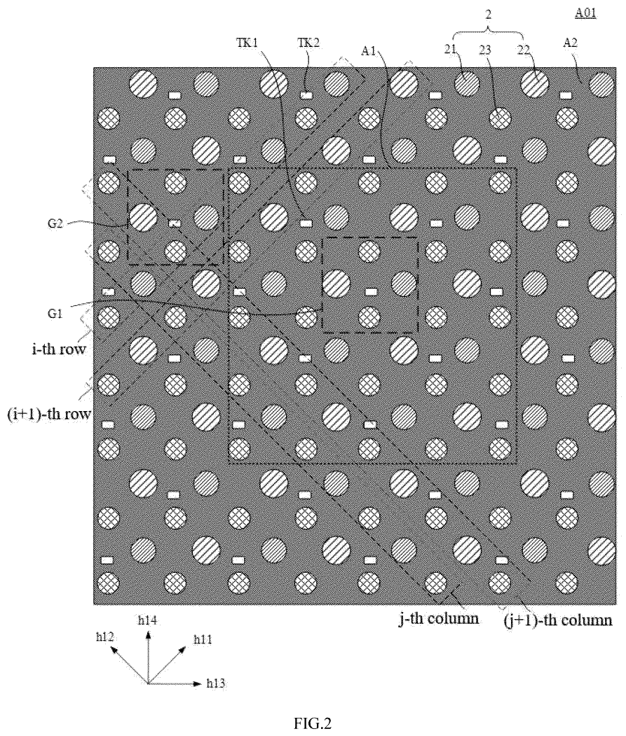

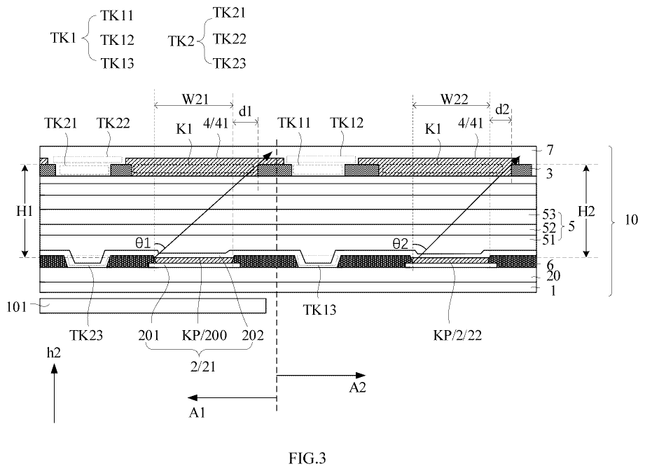

An embodiment of the present disclosure provides a display module, as shown in FIG. 1, which is a schematic top view of a display module 100 provided by an embodiment of the present disclosure. FIG. 2 is an enlarged schematic view of a region A01 in FIG. 1. FIG. 3 is a schematic cross-sectional view of a display module 100 provided by an embodiment of the present disclosure. The display module 100 includes a display panel 10 and a first optical sensor 101. Optionally, the first optical sensor 101 includes any one of an ambient light sensor, a fingerprint sensor, or a proximity sensor.

As shown in FIG. 1, FIG. 2 and FIG. 3, the display panel 10 includes a first display region A1 and a second display region A2, and a light transmittance of the first display region A1 is greater than or equal to a light transmittance of the second display region A2. Exemplarily, the second display region A2 may at least partially surround the first display region A1. FIG. 1 illustrates that the second display region A2 surrounds the first display region A1. An area of the second display region A2 may be greater than an area of the first display region A1.

Both the first display region A1 and the second display region A2 include a substrate 1, light-emitting units 2 and light transmitting holes. The light-emitting units 2 and light transmitting holes are located on a same side of the substrate 1. For ease of description of the embodiments of the present disclosure, the light transmitting holes in the first display region A1 are marked as first light transmitting holes TK1, and the light transmitting holes in the second display region A2 are marked as second light transmitting holes TK2.

In a direction h2 perpendicular to a plane of the substrate 1, the first optical sensor 101 at least partially overlaps with the first display region A1, the first optical sensor 101 does not overlap with the second display region A2, and the first light transmitting holes TK1 and the second light transmitting holes TK2 do not overlap with the light-emitting units 2. The first optical sensor 101 is located on a side of the substrate 1 away from a light exit side of the display panel 10. Optionally, the first optical sensor 101 may not be attached to the substrate 1.

Exemplarily, the display panel 10 may include a plurality of light-emitting units 2 with different light emitting colors. As shown in FIG. 2, the plurality of light-emitting units 2 include first color light-emitting units 21, second color light-emitting units 22, and third color light-emitting units 23. Optionally, the first color may be red, the second color may be green, and the third color may be blue.

Exemplarily, as shown in FIG. 3, the light-emitting unit 2 includes a first electrode 201, a light-emitting layer 200, and a second electrode 202 that are stacked. Optionally, the first electrode 201 may be an anode, and the second electrode 202 may be a cathode. Exemplarily, the cathode may be a full-surface structure covering the plurality of light-emitting units 2.

Optionally, the light-emitting unit 2 includes any one of an organic light-emitting diode (OLED), a quantum dot light-emitting diode (QLED), and a micro light-emitting diode (Micro LED).

When the first optical sensor 101 is in operation, light from the external environment can pass through the first light transmitting holes TK1 and be incident from one side of the display panel 10 to the first optical sensor 101 located on the other side of the display panel 10. The first optical sensor 101 may control the display panel 10 to perform a corresponding operation according to the received light. For example, the first optical sensor 101 may be an ambient light sensor, and the first optical sensor 101 can adjust the display brightness of the display panel 10 according to the intensity of the received ambient light. For example, when the outdoor brightness is relatively strong, the display brightness of display panel 10 is increased to allow a user to clearly see the picture. When the ambient brightness is relatively weak, for example, in indoor or nighttime environments, the display brightness of the display panel 10 is reduced to decrease the power consumption of the display panel. When the first optical sensor 101 is a fingerprint sensor, the first optical sensor 101 can cause the display panel 10 to perform an unlocking operation or other corresponding operations according to the intensity of the received fingerprint-reflected light. The design of the first light transmitting holes TK1 can meet the photosensitive requirement of the first optical sensor 101 disposed corresponding to the first display region A1.

In the embodiments of the present disclosure, the second display region A2 is a region in the display region of the display panel where the first optical sensor 101 is not disposed. In the embodiments of the present disclosure, by providing the second light transmitting holes TK2 in the second display region A2, a reflectance of the second display region A2 can be increased and the difference in reflectance between the second display region A2 and the first display region A1 can be reduced, compared with a design in which the second display region A2 does not include the light transmitting holes.

In the display module 100 provided by the embodiment of the present disclosure, by providing the first light transmitting holes TK1 in the first display region A1 of the display panel 10, the light transmittance of the first display region A1 can be improved, the intensity of the light entering the first optical sensor 101 can be increased, and the operating performance of the first optical sensor 101 can be improved.

Meanwhile, in the embodiments of the present disclosure, by providing the second light transmitting holes TK2 in the second display region A2, the reflectance of the second display region A2 can be increased, so that the reflectance of the second display region A2 approaches a reflectance of the first display region A1, which can reduce the difference in reflectance between the two regions, avoid the problem of visual unevenness that the first display region A1 appears obviously brighter than other regions in a screen-off state and improve the user's usage experience.

Moreover, by adopting this arrangement, while reducing the difference in reflectance between the first display region A1 and the second display region A2, there is no need to reduce the area occupied by the first light transmitting holes TK1 in the first display region A1, which can ensure that the first display region A1 has a higher light transmittance, thereby ensuring the operating performance of the first optical sensor 101.

Exemplarily, as shown in FIG. 2, a density of the light-emitting units 2 in the first display region A1 is equal to a density of the light-emitting units 2 in the second display region A2, to ensure that the display effects of the two regions are close to or the same as each other, thereby improving the display uniformity. The density of the light-emitting units 2 is the number of the light-emitting units 2 in a display region per unit area.

Exemplarily, as shown in FIG. 2, the first display region A1 includes a first group G1, and the second display region A2 includes a second group G2. Both the first group G1 and the second group G2 include light-emitting units 2 and a light transmitting hole. After being translated, the light-emitting units 2 and the light transmitting hole in the first group G1 at least partially overlap with the light-emitting units 2 and the light transmitting hole in the second group G2, respectively. Based on this arrangement, the position of the light transmitting hole in the second display region A2 relative to the light-emitting units 2 in the second display region A2 may be the same as the position of the light transmitting hole in the first display region A1 relative to the light-emitting units 2 in the first display region A1, so that the distribution rules of the light transmitting holes in the first display region A1 and the second display region A2 can be made as consistent as possible, which is beneficial to improving the display consistency of the display panel.

As shown in FIG. 2, in the first display region A1 and the second display region A2, the light transmitting holes are both located between the second color light-emitting unit 22 and the first color light-emitting unit 21 in a third direction h13, and are located between two adjacent third color light-emitting units 23 in a fourth direction h14.

Optionally, an area of the second light transmitting hole TK2 is smaller than or equal to an area of the first light transmitting hole TK1. FIG. 2 illustrates that the area of the second light transmitting hole TK2 is equal to the area of the first light transmitting hole TK1 in the first display region A1. Based on this arrangement, it can be ensured that the first display region A1 has a larger light transmittance, to satisfy the photosensitive requirement of the first optical sensor 101 disposed corresponding to the first display region A1. Moreover, while increasing the reflectance of the second display region A2 and reducing the difference in reflectance between the first display region A1 and the second display region A2, it can also be avoided that the reflectance of the second display region A2 is increased excessively, and it can be ensured that the second display region A2 meets basic reflectance specification requirements.

Exemplarily, a total area proportion m1 of the plurality of first light transmitting holes TK1 in the display panel 10 is greater than a total area proportion m2 of the plurality of second light transmitting holes TK2 in the display panel 10. The number of the first light transmitting holes TK1 is n1, and the number of the second light transmitting holes TK2 is n2. The area of a single first light transmitting hole TK1 is S1, the area of a single second light transmitting hole TK2 is S2, and the area of the display panel is S0, then m1=n1×S1/S0, and m2=n2×S2/S0.

Optionally, the total area proportion m1 of the plurality of first light transmitting holes TK1 satisfies: 1.5%≤m1≤2%. Optionally, m1 may be 1.5%, 1.6%, 1.7%, 1.8%, 1.9%, or 2%.

Exemplarily, the area ratio m2 of the plurality of second light transmitting holes TK2 satisfies: 0.5%≤m2≤1%. Optionally, m2 may be 0.5%, 0.6%, 0.7%, 0.8%, 0.9%, or 1%.

Based on this arrangement, excessive increase of the reflectance of the second display region A2 is avoided. While reducing the difference in reflectance between the first display region A1 and the second display region A2, the basic display effect of the second display region A2 is not affected.

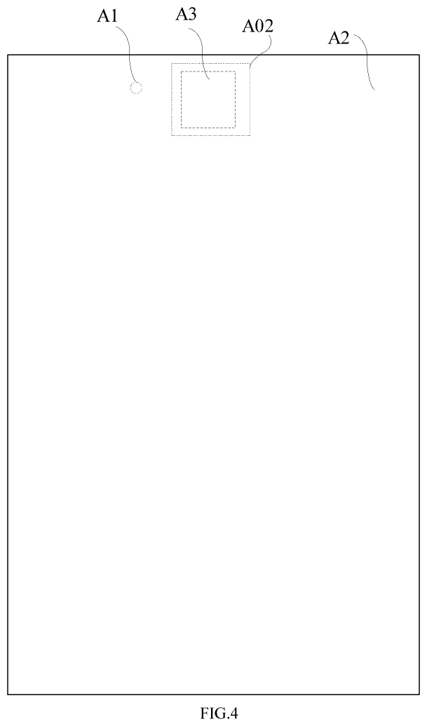

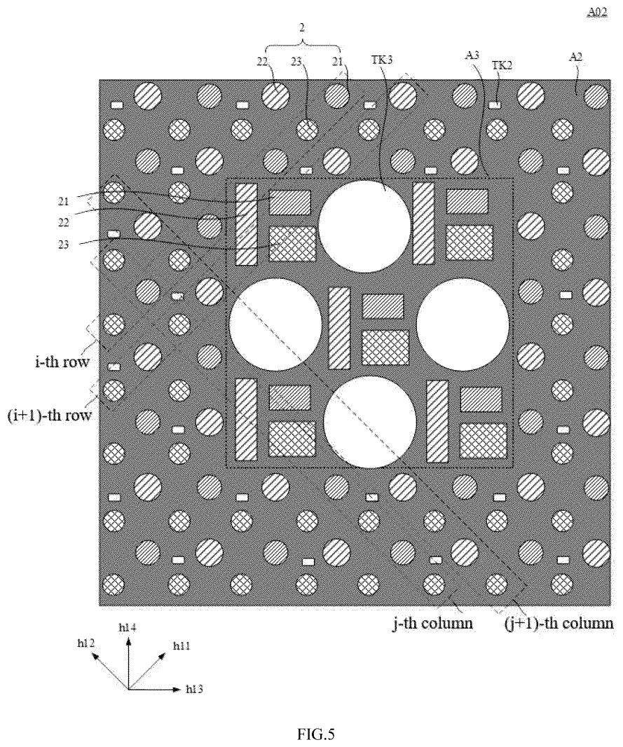

Exemplarily, as shown in FIG. 4, which is a schematic top view of another display module 100 provided by an embodiment of the present disclosure, the display panel 10 further includes a third display region A3. As shown in conjunction with FIG. 5, which is an enlarged schematic view of a region A02 in FIG. 4, the third display region A3 also includes light-emitting units 2, and a density of the light-emitting units 2 in the third display region A3 is smaller than or equal to the density of the light-emitting units 2 in the second display region A2. Based on this arrangement, a light transmittance of the third display region A3 can be improved. FIG. 5 illustrates that the density of the light-emitting units 2 in the third display region A3 is smaller than the density of the light-emitting units 2 in the second display region A2.

Exemplarily, in the embodiment of the present disclosure, the pixel arrangement rules of the first display region A1, the second display region A2, and the third display region A3 may be the same or different. FIG. 2 illustrates that the pixel arrangement rules of the first display region A1 and the second display region A2 are the same. FIG. 5 illustrates that the pixel arrangement rules of the third display region A3 and the second display region A2 are different.

As shown in FIG. 2 and FIG. 5, in the first display region A1 and the second display region A2, an i-th row of light-emitting units include the first color light-emitting units 21 and the third color light-emitting units 23 alternately arranged along a first direction h11; an (i+1)-th row of light-emitting units include the second color light-emitting units 22 and the third color light-emitting units 23 alternately arranged along the first direction h11; a j-th column of light-emitting units include the first color light-emitting units 21 and the third color light-emitting units 23 alternately arranged along a second direction h12; and a (j+1)-th column of light-emitting units include the second color light-emitting units 22 and the third color light-emitting unit 23 alternately arranged along the second direction h12.

As shown in FIG. 5, in the third display region A3, the first color light-emitting unit 21 and the third color light-emitting unit 23 are arranged along the fourth direction h14, and both the first color light-emitting unit 21 and the third color light-emitting unit 23 overlap with the second color light-emitting unit 22 in the third direction h13.

Optionally, as shown in FIG. 5, the third display region A3 may include third light transmitting holes TK3. Exemplarily, an area of the third light transmitting hole TK3 may be greater than the area of the first light transmitting hole TK1 or the second light transmitting hole TK2, to further increase the light transmittance of the third display region A3.

Optionally, as shown in conjunction with FIG. 6, which is a schematic cross-sectional view of a second display region and a third display region of a display module provided by an embodiment of the present disclosure, the display module 100 further includes a second optical sensor 102. Along the direction h2 perpendicular to the plane of the substrate 1, the second optical sensor 102 at least partially overlaps with the third display region A3. Exemplarily, the second optical sensor 102 at least partially does not overlap with the first display region A1 and the second display region A2. The second optical sensor 102 is located on the side of the substrate 1 away from the light exit side of the display panel 10. Optionally, the second optical sensor 102 may not be attached to the substrate 1.

Optionally, the second optical sensor 102 includes a camera. The provision of the second optical sensor 102 can enrich the functions of the display module 100 and improve the user's experience.

In the embodiment of the disclosure, by providing the light-emitting units 2 in both the first display region A1 and the third display region A3, while enabling the display panel 10 to have non-display functions such as brightness sensing and photographing, the display panel 10 can be enabled to achieve a full-screen display effect, which can improve the user's experience. Exemplarily, as shown in FIG. 3, the display panel 10 further includes a light-shielding layer 3. At least a part of the light-shielding layer 3 is located on a side of the light-emitting units 2 close to the light exit side of the display panel 10. The light-shielding layer 3 can avoid color crosstalk of light emitted from two adjacent light-emitting units 2 that emit different colors of light. Optionally, the light-shielding layer 3 includes a black matrix (BM) formed from a metal material, a pigment (such as carbon black), or a resin material of a dye, etc.

As shown in FIG. 3 and FIG. 6, the light-shielding layer 3 includes a plurality of first openings K1 and a plurality of second openings. Along a direction perpendicular to the plane of the substrate 1, the light-emitting units 2 at least partially overlaps with their respective first openings K1. The emergent light of the light-emitting units 2 may be emitted through their respective first openings K1.

In an embodiment of the present disclosure, at least one of the light transmitting holes in the second display region A2, the light transmitting holes in the first display region A1, and the light transmitting holes in the third display region A3 includes a second opening. For ease of description of the embodiment of the present disclosure, the second opening in the first display region A1 is marked as a first light transmitting sub-hole TK11, the second opening in the second display region A2 is marked as a second light transmitting sub-hole TK21, and the second opening in the third display region A3 is marked as a seventh light transmitting sub-hole TK31.

That is, as shown in FIG. 3 and FIG. 6, the first light transmitting hole TK1 includes the first light transmitting sub-hole TK11. The first light transmitting sub-hole TK11 penetrates through the light-shielding layer 3 located in the first display region A1. The provision of the first light transmitting sub-hole TK11 can improve the light transmittance of the region where the first light transmitting hole TK1 is located in the light-shielding layer 3. When the first optical sensor 101 is in operation, the ambient light can pass through the light-shielding layer 3 from one side of the display panel 10 through the first light transmitting sub-hole TK11 to be emitted to the first optical sensor 101 located on the other side of the display panel.

As shown in FIG. 3, the second light transmitting hole TK2 includes the second light transmitting sub-hole TK21. The second light transmitting sub-hole TK21 penetrates through the light-shielding layer 3 located in the second display region A2. The provision of the second light transmitting sub-hole TK21 can improve the reflectance of the region where the second light transmitting hole TK2 is located and reduce the difference in reflectance between the second display region A2 and the first display region A1.

As shown in FIG. 6, the third light transmitting hole TK3 includes the seventh light transmitting sub-hole TK31. The seventh light transmitting sub-hole TK31 penetrates through the light-shielding layer 3 located in the third display region A3. The provision of the seventh light transmitting sub-hole TK31 can improve the light transmittance of the region where the third light transmitting hole TK3 is located. When the display panel 10 is in operation, the ambient light can be emitted from one side of the display panel to the second optical sensor 102 located on the other side of the display panel through the seventh light transmitting sub-hole TK31.

Exemplarily, the first light transmitting sub-hole TK11, the second light transmitting sub-hole TK21, and the seventh light transmitting sub-hole TK31 can be formed in the same patterning process to simplify the manufacturing process of the display panel.

Exemplarily, as shown in FIG. 3 and FIG. 6, the display panel 10 further includes a color filter layer (CF) 4. The color filter layer 4 is at least partially located in the first opening K1 of the light-shielding layer 3. Along the direction perpendicular to the plane of the substrate 1, the light-emitting unit 2 at least partially overlaps with the color filter layer 4. The color filter layer 4 only allows light of a specific wavelength to pass through, which can enable pixels to emit light of a specific color, thereby reducing the reflectance of the display panel 10.

Exemplarily, as shown in FIG. 3, the display panel 10 may include a plurality of color filter layers 4 having different emitted light colors. For example, the plurality of color filter layers 4 include a first-color color filter layer 41, a second-color color filter layer 42, and a third-color color filter layer 43. The first-color color filter layer 41 is at least partially located in the first sub-opening K11, the second-color color filter layer 42 is at least partially located in the second sub-opening K12, and the third-color color filter layer 43 is at least partially located in the third sub-opening K13.

Along the direction h2 perpendicular to the plane of the substrate 1, the first-color color filter layer 41 at least partially overlaps with the first color light-emitting unit 21, the second-color color filter layer 42 at least partially overlaps with the second color light-emitting unit 22, and the third-color color filter layer 43 at least partially overlaps with the third color light-emitting unit 23. The first-color color filter layer 41 only allows light of the first color to be emitted, the second-color color filter layer 42 only allows light of the second color to be emitted, and the third-color color filter layer 43 only allows light of the third color to be emitted.

Exemplarily, as shown in FIG. 3, at least a part of the color filter layer 4 is located on a side of the light-shielding layer 3 away from the substrate 1. Optionally, the light-shielding layer 3 may be at least partially covered by the color filter layer 4.

In an embodiment of the present disclosure, the color filter layer 4 includes a third opening. Along the direction h2 perpendicular to the plane of the substrate 1, the third opening at least partially does not overlap with the light-emitting unit 2.

Exemplarily, at least one of the light transmitting holes in the second display region A2, the light transmitting holes in the first display region A1, and the light transmitting holes in the third display region A3 includes a third opening. For ease of description of the embodiment of the present disclosure, the third opening in the first display region A1 is marked as a third light transmitting sub-hole TK12, the third opening in the second display region A2 is marked as a fourth light transmitting sub-hole TK22, and the third opening in the third display region A3 is marked as an eighth light transmitting sub-hole TK32.

That is, as shown in FIG. 3 and FIG. 6, the first light transmitting hole K1 further includes the third light transmitting sub-hole TK12. The third light transmitting sub-hole TK12 penetrates through the color filter layer 4 located in the first display region A1. Along the direction h2 perpendicular to the plane of the substrate 1, the third light transmitting sub-hole TK12 at least partially overlaps with the first light transmitting sub-hole TK11. The provision of the third light transmitting sub-hole TK12 can improve the light transmittance of the region where the first light transmitting hole TK1 is located in the color filter layer 4. When the first optical sensor 101 is in operation, the ambient light can pass through the color filter layer 4 from one side of the display panel through the third light transmitting sub-hole TK12 to be emitted to the first optical sensor 101 located on the other side.

As shown in FIG. 3, the second light transmitting hole TK2 further includes the fourth light transmitting sub-hole TK22. The fourth light transmitting sub-hole TK22 penetrates through the color filter layer 4 located in the second display region A2. Along the direction h2 perpendicular to the plane of the substrate 1, the fourth light transmitting sub-hole TK22 at least partially overlaps with the second light transmitting sub-hole TK21. The provision of the fourth light transmitting sub-hole TK22 can further improve the reflectance of the region where the second light transmitting hole TK2 is located in the color filter layer 4, thereby reducing the difference in reflectance between the second display region A2 and the first display region A1, which is beneficial to further improving the visual effect consistency between different regions of the display panel 10 in a screen-off state.

As shown in FIG. 6, the third light transmitting hole TK3 further includes the eighth light transmitting sub-hole TK32. The eighth light transmitting sub-hole TK32 penetrates through the color filter layer 4 located in the third display region A3. Along the direction perpendicular to the plane of the substrate 1, the eighth light transmitting sub-hole TK32 at least partially overlaps with the seventh light transmitting sub-hole TK31. The provision of the eighth light transmitting sub-hole TK32 can improve the light transmittance of the region where the third light transmitting hole TK3 is located in the color filter layer 4. When the display panel 10 is in operation, the ambient light can pass through the color filter layer 4 from one side of the display panel 10 through the eighth light transmitting sub-hole TK32 to be emitted to the second optical sensor 102 located on the other side of the display panel 10.

Exemplarily, the third light transmitting sub-hole TK12, the fourth light transmitting sub-hole TK22, and the eighth light transmitting sub-hole TK32 can be formed in the same patterning process to simplify the manufacturing process of the display panel 10.

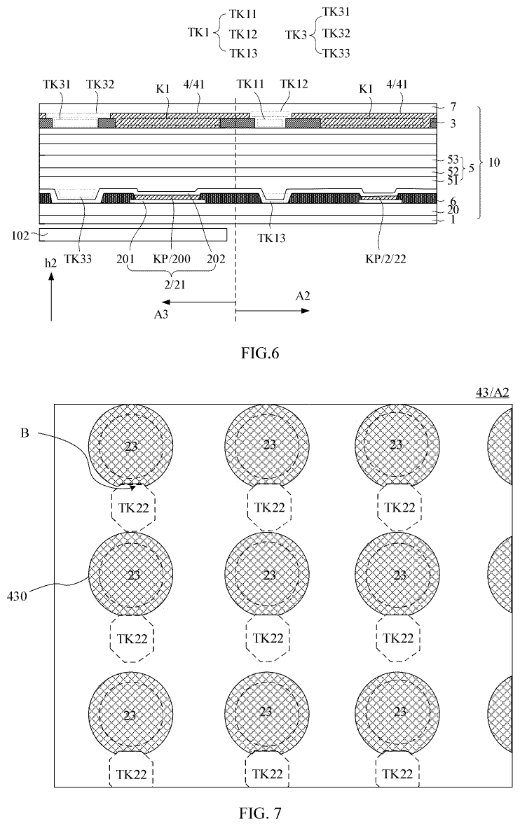

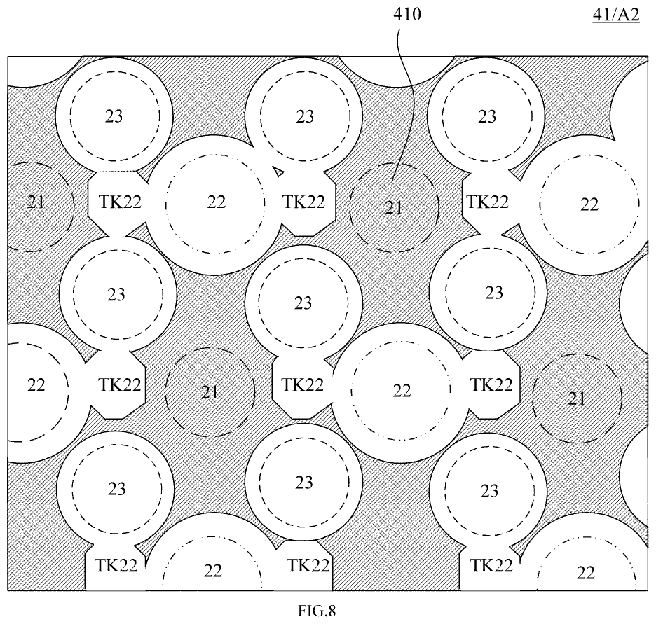

It should be noted that the third light transmitting sub-hole TK21, the fourth light transmitting sub-hole TK22, and the eighth light transmitting sub-hole TK32 may be located at an edge of the corresponding color filter layer 4. That is, a non-opening structure of the color filter layer 4 partially surrounds the third light transmitting sub-hole TK21 or the fourth light transmitting sub-hole TK22. In this case, as shown in FIG. 7, which is a schematic top view of the third-color color filter layer located in the second display region provided by an embodiment of the present disclosure, the third-color color filter layer 43 includes a plurality of third-color color filter units 430 spaced apart from each other. The plurality of third-color color filter units 430 are provided in one-to-one correspondence with a plurality of third color light-emitting units 23 (FIG. 7 shows positions of the third color light-emitting units 23 by dashed lines). An edge of at least some of the third-color color filter units 430 includes a notch B. An orthographic projection of the third light transmitting sub-hole TK22 onto the plane of the substrate 1 covers an orthographic projection of the notch B onto the plane of the substrate 1.

As shown in FIG. 7, an area of the third-color color filter unit 430 may be slightly larger than an area of third color light-emitting unit 23, and an orthographic projection of the third-color color filter unit 430 onto the plane of the substrate 1 may cover an orthographic projection of the third color light-emitting unit 23 onto the plane of the substrate 1.

Alternatively, as shown in FIG. 8, which is a schematic top view of a first-color color filter layer located in the second display region provided by an embodiment of the present disclosure, the first-color color filter layer 41 includes a plurality of first-color color filter units 410, and at least some of the first-color color filter units 410 are connected to each other. In the first-color color filter layer 41, the first-color color filter units 410 are provided at positions that avoid the second color light-emitting units 22 and the third color light-emitting units 23. That is, in the first-color color filter layer 41, in addition to the through holes disposed at the positions of the second color light-emitting units 22 and the third color light-emitting units 23 (FIG. 8 illustrates the positions of the first color light-emitting units 21, the second color light-emitting units 22, and the third color light-emitting units 23 in dotted lines), through holes are also required to be disposed at the positions corresponding to the first light transmitting holes (not shown in FIG. 8) and the second light transmitting holes TK2. These through holes are the fourth light transmitting sub-holes TK22.

FIG. 7 and FIG. 8 illustrate that the shape of the fourth light transmitting sub-hole TK22 is a polygon. Of course, the shape of the fourth light transmitting sub-hole TK22 can also be designed as other shapes, and the shape of the light transmitting hole is not limited in the embodiments of the present disclosure.

The hole formations of the color filter layer 4 located in the first display region A1 and the third display region A3 are similar to those of the second display region A2, and will not be described one by one here.

Exemplarily, as shown in FIG. 3 and FIG. 6, the display panel 10 further includes an encapsulation layer 5. The color filter layer 4 is located on a side of the encapsulation layer 5 away from the light-emitting units 2. The color filter layer 4 can be reused as a polarizer, which can reduce the reflectance of the display panel 10 while reducing the thickness of the display panel 10, which is conducive to the lightweight design of the display panel.

Optionally, the encapsulation layer 5 includes a first encapsulation layer 51, a second encapsulation layer 52, and a third encapsulation layer 53 that are stacked. The first encapsulation layer 51 and the third encapsulation layer 53 may include an inorganic encapsulation layer, and the second encapsulation layer 52 may include an organic encapsulation layer.

Optionally, as shown in FIG. 3 and FIG. 6, the display panel 10 further includes an optical adhesive layer 7. Exemplarily, in the embodiment of the disclosure, the reflectance of the first display region A1 and the reflectance of the second display region A2 can be further adjusted by adjusting a thickness of the optical adhesive layer 7.

Exemplarily, as shown in FIG. 3 and FIG. 6, the display panel 10 further includes a pixel definition layer (PDL) 6. The pixel definition layer 6 includes pixel openings KP. At least some of the light-emitting units 2 are located in the pixel openings KP. In particular, the pixel openings KP can be formed in the regions overlapping with the light-emitting units 2 to expose the first electrodes 201 of the light-emitting units 2. The light-emitting layer 200 located on a side of the first electrodes 201 away from the substrate 1 is at least partially formed in the pixel openings KP.

In an embodiment of the present disclosure, the pixel definition layer 6 further includes fourth openings. Along the direction perpendicular to the plane of the substrate 1, the fourth openings do not overlap with the light-emitting units 2. At least one of the light transmitting holes in the second display region A2, the light transmitting holes in the first display region A1, and the light transmitting holes in the third display region A3 includes the fourth opening. For ease of description of the embodiment of the present disclosure, the fourth opening in the first display region A1 is marked as a fifth light transmitting sub-hole TK13, the fourth opening in the second display region A2 is marked as a sixth light transmitting sub-hole TK23, and the fourth opening in the third display region A3 is marked as a ninth light transmitting sub-hole TK33.

That is, as shown in FIG. 3 and FIG. 6, the first light transmitting hole TK1 further includes the fifth light transmitting sub-hole TK13. The fifth light transmitting sub-hole TK13 penetrates through the pixel definition layer 6 located in the first display region A1. Along the direction h2 perpendicular to the plane of the substrate 1, the fifth light transmitting sub-hole TK13 at least partially overlaps with the first light transmitting sub-hole TK11 and the third light transmitting sub-hole TK12. The provision of the fifth light transmitting sub-hole TK13 can improve the light transmittance of the region where the first light transmitting hole TK1 is located in the pixel definition layer 6. When the first optical sensor 101 is in operation, more ambient light can pass through the pixel definition layer 6 from one side of the display panel 10 through the fifth light transmitting sub-hole TK13 to be emitted to the first optical sensor 101 located on the other side of the display panel 10, thereby improving the operating performance of the first optical sensor 101.

As shown in FIG. 3, the second light transmitting hole TK2 further includes the sixth light transmitting sub-hole TK23. The sixth light transmitting sub-hole TK23 penetrates through the pixel definition layer 6 located in the second display region A2. In the direction h2 perpendicular to the plane of the substrate 1, the sixth light transmitting sub-hole TK23 at least partially overlaps with the second light transmitting sub-hole TK21 and the fourth light transmitting sub-hole TK22. The provision of the sixth light transmitting sub-hole TK23 can further improve the reflectance of the region where the second light transmitting hole TK2 is located, thereby reducing the difference in reflectance between the second display region A2 and the first display region A1, which is beneficial to further improving the visual effect consistency between different regions of the display panel in a screen-off state.

As shown in FIG. 6, the third light transmitting hole TK3 further includes the ninth light transmitting sub-hole TK33. The ninth light transmitting sub-hole TK33 penetrates through the pixel definition layer 6 located in the third display region A3. Along the direction h2 perpendicular to the plane of the substrate 1, the ninth light transmitting sub-hole TK33 at least partially overlaps with the seventh light transmitting sub-hole TK31 and the eighth light transmitting sub-hole TK32. The provision of the ninth light transmitting sub-hole TK33 can improve the light transmittance of the region where the third light transmitting hole TK3 is located. When the display panel 10 is in operation, the ambient light can pass through the pixel definition layer 6 from one side of the display panel 10 through the ninth light transmitting sub-hole TK33 to be emitted to the second optical sensor 102 located on the other side of the display panel 10.

Exemplarily, the fifth light transmitting sub-hole TK13, the sixth light transmitting sub-hole TK23 and the ninth light transmitting sub-hole TK33 can be formed in the same patterning process to simplify the manufacturing process of the display panel.

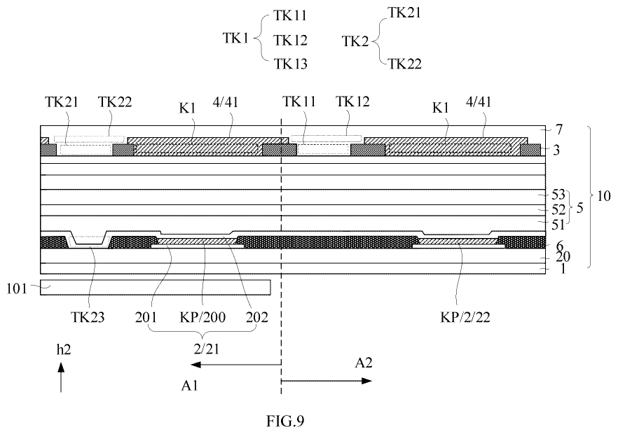

In another optional implementation, as shown in FIG. 9, which is a schematic cross-sectional view of yet another display panel provided by an embodiment of the present disclosure, the second light transmitting hole TK2 may include only the second light transmitting sub-hole TK21 and the fourth light transmitting sub-hole TK22. That is, the pixel definition layer 6 may not include the fourth opening in the second display region A2. Based on this arrangement, it can be avoided that the reflectance of the region where the second light transmitting hole TK2 is located is increased excessively, which can ensure that the basic display effect of the second display region A2 is not affected.

In addition, in the case where the target reflectance of the second display region A2 is determined, by avoiding providing the fourth opening corresponding to the second light transmitting hole TK2 in the pixel definition layer 6, it is also possible to avoid setting the area of the individual second light transmitting hole TK2 to be too small. The smaller the area of the second light transmitting hole TK2 is, the higher the requirement for the exposure process is. Therefore, by adopting this arrangement, the process difficulty can be reduced, which is conducive to improving the process yield. The target reflectance refers to the reflectance of the second display region when the difference in reflectance between the second display region and the first display region is such that the abnormal light emission problem of the first display region is indistinguishable to the naked eye.

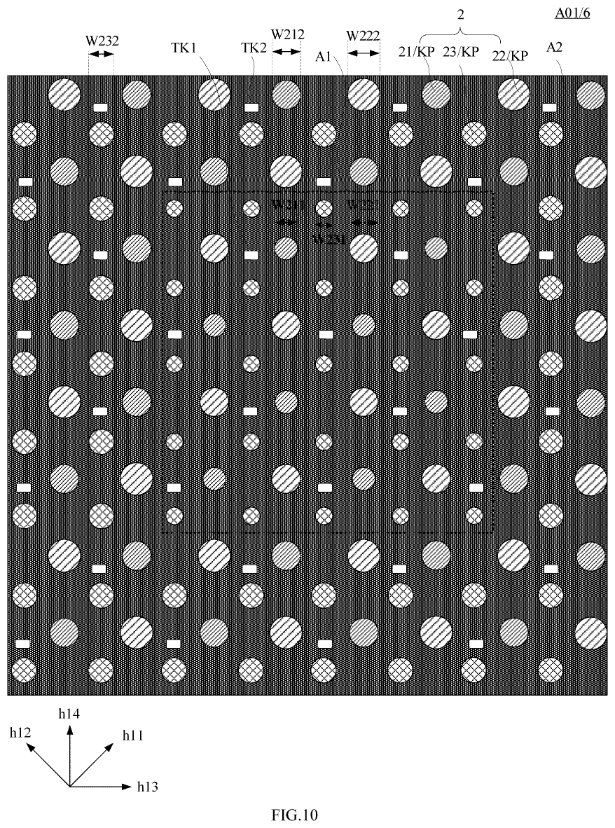

Optionally, as shown in FIG. 10, which is a schematic top view of a pixel definition layer in the region A01 in FIG. 1, along a direction parallel to the plane of the substrate 1, a width of the pixel opening KP in the first display region A1 is smaller than a width of the pixel opening KP in the second display region A2. A width direction of the pixel opening KP in the first display region A1 is parallel to a width direction of the pixel opening KP in the second display region A2.

The pixel opening KP can expose the first electrode of the light-emitting unit 2, and the first electrode can reflect light. Therefore, the larger the area of the pixel opening KP, the higher the reflectance of that region. In the embodiments of the present disclosure, by making the width of the pixel opening KP1 in the first display region A1 smaller than the width of the pixel opening KP2 in the second display region A2, an area of the pixel opening KP in the first display region A1 is smaller than an area of the pixel opening KP in the second display region A2, so that the reflectance of the light emitting region where the light-emitting unit 2 is located in the first display region A1 is smaller than the reflectance of the light emitting region where the light-emitting unit 2 is located in the second display region A2, thereby compensating for the overall difference in reflectance between the second display region A2 and the first display region A1 caused by the provision of the light transmitting holes in the related art, and thus improving the visual effect consistency of the display panel 10 in a screen-off state.

It should be noted that, as shown in FIG. 10, both the first display region A1 and the second display region A2 includes a plurality of light-emitting units 2 of different colors. Correspondingly, the first display region A1 and the second display region A2 include a plurality of pixel openings for accommodating the light-emitting units 2 of different colors, and the width of the pixel opening KP in the first display region A1 is smaller than the width of the pixel opening KP in the second display region A2, which means that for the pixel openings KP for accommodating the light-emitting units 2 of the same color in the first display region A1 and the second display region A2, the width of the pixel opening KP in the first display region A1 is smaller than the width of the pixel opening KP in the second display region A2.

As shown in FIG. 10, for the first color light-emitting unit 21, a width W211 of the pixel opening KP in the first display region A1 in the third direction h13 is smaller than a width W212 of the pixel opening KP in the second display region A2 in the third direction h13; for the second color light-emitting unit 22, the width W221 of the pixel opening KP in the first display region A1 in the third direction h13 is smaller than a width W222 of the pixel opening KP in the second display region A2 in the third direction h13; and for the third color light-emitting unit 22, a width W231 of the pixel opening KP in the first display region A1 in the third direction h13 is smaller than a width W232 of the pixel opening KP in the second display region A2 in the third direction h13.

Exemplarily, the area of the pixel opening KP in the first display region A1 is S11, and the area of the pixel opening KP in the second display region A2 is S21, where 1%≤(S21−S11)/S21≤3%. Based on this arrangement, the area difference of the pixel openings KP corresponding to the light-emitting units 2 of the same color in the first display region A1 and the second display region A2 can be prevented from being too large. While reducing the difference in reflectance of the first display region A1 and the second display region A2, it can be ensured that the lifetime and the color shift degree of the light-emitting units 2 of the same color in the first display region A1 and the second display region A2 tend to be consistent, which is beneficial to improving the display uniformity.

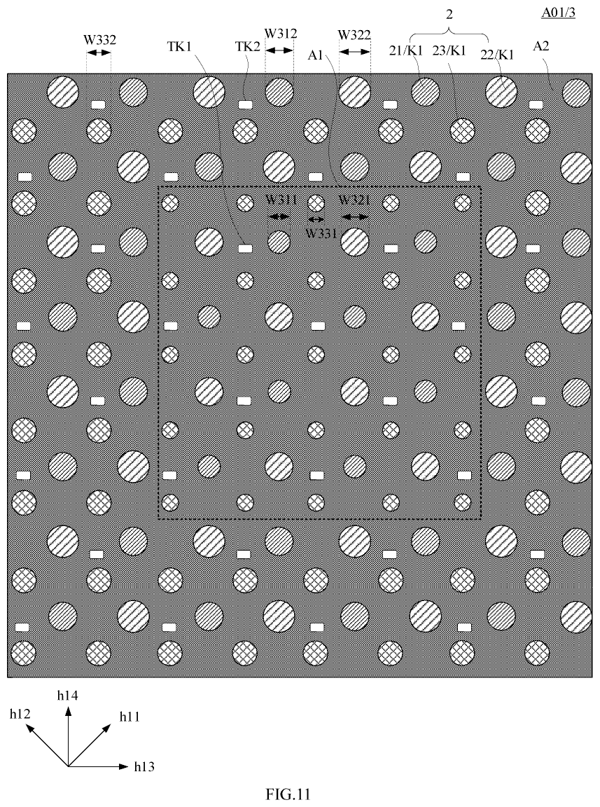

Optionally, as shown in FIG. 11, which is a schematic top view of a light-shielding layer in the region A01 in FIG. 1, along the direction parallel to the plane of the substrate 1, the width of the first opening K1 in the first display region A1 is smaller than or equal to the width of the first opening K1 in the second display region A2. A width direction of the first opening K1 in the first display region A1 is parallel to a width direction of the first opening K1 in the second display region A2.

The first opening K1 can expose metal structures such as the second electrode 202 and the first electrode 201 of the light-emitting unit 2. Therefore, the larger the area of the first opening K1, the higher the reflectance of that region. In the embodiment of the present disclosure, by making the width of the first opening K1 in the first display region A1 smaller than or equal to the width of the first opening K1 in the second display region A2, an area of the first opening K1 in the first display region A1 can be smaller than or equal to an area an area of the first opening K1 in the second display region A2, so that the reflectance of the light emitting region where the light-emitting unit 2 is located in the first display region A1 is smaller than or equal to the reflectance of the light emitting region where the light-emitting unit 2 is located in the second display region A2, thereby further compensating for the overall difference in reflectance between the first display region A1 and the second display region A2 caused by the provision of the light transmitting holes in the related art, and thus improving the visual effect consistency of the display panel 10 in a screen-off state.

It should be noted that, as shown in FIG. 11, both the first display region A1 and the second display region A2 include a plurality of light-emitting units 2 of different colors. Correspondingly, in the light-shielding layer 3, both the first display region A1 and the second display region A2 include first openings K1 corresponding to the plurality of light-emitting units 2 of different colors. The width of the first opening K1 in the first display region A1 is smaller than or equal to the width of the first opening K1 in the second display region A2, which means that for the first openings K1 corresponding to the light-emitting units 2 of the same color in the first display region A1 and the second display region A2, the width of the first opening K1 in the first display region A1 is smaller than or equal to the width of the first opening K1 in the second display region A2.

As shown in FIG. 11, for the first color light-emitting unit 21, a width W311 of the first opening K1 in the first display region A1 in the third direction h13 is smaller than a width W312 of the first opening K1 in the second display region A2 in the third direction h13; for the second color light-emitting unit 22, a width W321 of the first opening K1 in the first display region A1 in the third direction h13 is smaller than a width W322 of the first opening K1 in the second display region A2 in the third direction h13; and for the third color light-emitting unit 23, a width W331 of the first opening K1 in the first display region A1 in the third direction h13 is smaller than a width W332 of the first opening K1 in the second display region A2 in the third direction h13.

Optionally, the area of the first opening K1 in the first display region A1 is S12, and the area of the first opening K1 in the second display region A2 is S22, where 1%≤(S22−S12)/S22≤5%. Based on this arrangement, the area difference between the first openings K1 corresponding to the light-emitting units 2 of the same color in the first display region A1 and the second display region A2 can be prevented from being too large. While reducing the difference in reflectance between the first display region A1 and the second display region A2, it can be ensured that the color shift degree of the light-emitting units 2 of the same color in the first display region A1 and the second display region A2 tend to be consistent, which is beneficial to improving the display uniformity.

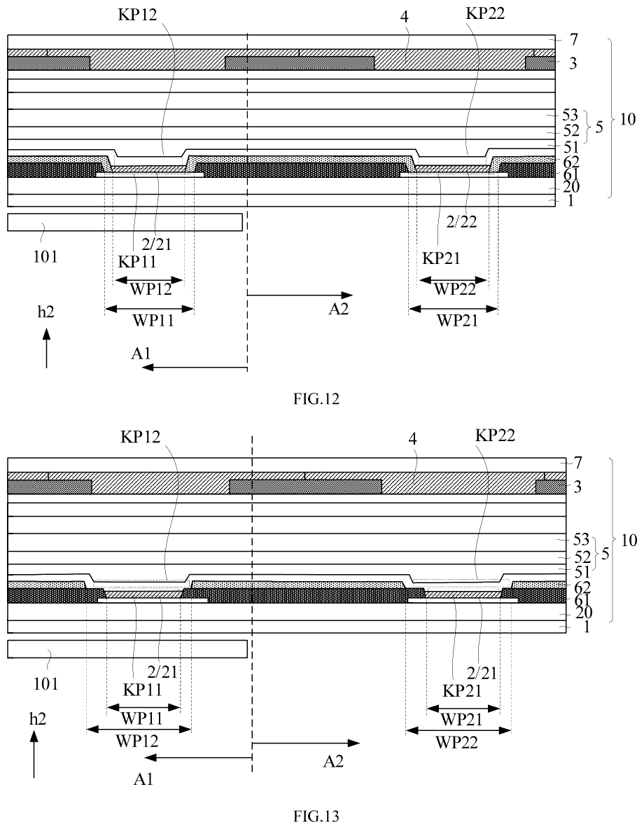

Optionally, as shown in FIG. 12 and FIG. 13, FIG. 12 and FIG. 13 are schematic cross-sectional views of a first display region and a second display region of further two display modules provided by embodiments of the present disclosure, the display panel 10 includes a first pixel definition layer 61 and a second pixel definition layer 62 that are stacked. The first pixel definition layer 61 is located on a side of the second pixel definition layer 62 close to the substrate 1. A light transmittance of the first pixel definition layer 61 is smaller than or equal to a light transmittance of the second pixel definition layer 62. Optionally, the first pixel definition layer 61 includes a black pixel definition layer (BPDL). Both the first pixel definition layer 61 and the light-shielding layer 3 can effectively absorb light, which can further reduce ambient light reflection, improve display contrast, and improve the display effect of the display panel 10. The second pixel definition layer 62 includes a normal pixel definition layer (NPDL).

Exemplarily, the first pixel definition layer 61 includes a plurality of first pixel openings, and the second pixel definition layer 62 includes a plurality of second pixel openings. For ease of description of the embodiments of the present disclosure, in the following, the first pixel opening in the first display region A1 is marked as a first pixel sub-opening KP11, and the second pixel opening in the first display region A1 is marked as a second pixel sub-opening KP12. Moreover, the first pixel opening in the second display region A2 is marked as a third pixel sub-opening KP21, and the second pixel opening in the second display region A2 is marked as a fourth pixel sub-opening KP22.

That is, as shown in FIG. 12 and FIG. 13, the first pixel definition layer 61 includes the first pixel sub-opening KP11 and the third pixel sub-opening KP21. The first pixel sub-opening KP11 is located in the first display region A1, and the third pixel sub-opening KP21 is located in the second display region A2. Both the first pixel sub-opening KP11 and the third pixel sub-opening KP21 penetrate through the first pixel definition layer 61.

The second pixel definition layer 62 includes the second pixel sub-opening KP12 and the fourth pixel sub-opening KP22. The second pixel sub-opening KP12 is located in the first display region A1, and the fourth pixel sub-opening KP22 is located in the second display region A2. Both the second pixel sub-opening KP12 and the fourth pixel sub-opening KP22 penetrate through the second pixel definition layer 62.

Along the direction h2 perpendicular to the plane of the substrate 1, the first pixel sub-opening KP11 at least partially overlaps with the second pixel sub-opening KP12, and the third pixel sub-opening KP21 at least partially overlaps with the fourth pixel sub-opening KP22.

In the embodiments of the present disclosure, by providing the first pixel definition layer 61 and the second pixel definition layer 62 and providing the pixel openings in both the first pixel definition layer 61 and the second pixel definition layer 62, the reflective area and the light-emitting area of the light-emitting regions where the light-emitting units 20 are located in the first display region A1 and the second display region A2 are separately adjusted by adjusting the widths of the two pixel openings respectively located in the first pixel definition layer 61 and the second pixel definition layer 62, which reduces the difference in reflectance between the first display region A1 and the second display region A2 and improves the visual effect consistency while being conducive to improving the design freedom of the display panel 10.

Optionally, the fourth opening may penetrate through both the first pixel definition layer 61 and the second pixel definition layer 62. Alternatively, in an embodiment of the present disclosure, the fourth opening may only penetrate through the first pixel definition layer 61 having a lower light transmittance. That is, in the second pixel definition layer 62 having a higher light transmittance, no hole formation design is performed in the region corresponding to the light transmitting hole.

Exemplarily, as shown in FIG. 12 and FIG. 13, for the light-emitting units 2 having the same light emitting color in the first display region A1 and the second display region A2, in the embodiments of the present disclosure, a width WP11 of the first pixel sub-opening KP11 may be equal to a width WP21 of the third pixel sub-opening KP21, and a width WP12 of the second pixel sub-opening KP12 may be equal to a width WP22 of the fourth pixel sub-opening KP22. FIG. 12 illustrates that the width WP11 of the first pixel sub-opening KP11 is greater than the width WP12 of the second pixel sub-opening KP12, and the width WP21 of the third pixel sub-opening KP21 is greater than the width WP22 of the fourth pixel sub-opening KP22. FIG. 13 illustrates that the width WP11 of the first pixel sub-opening KP11 is smaller than the width WP12 of the second pixel sub-opening KP12, and the width WP21 of the third pixel sub-opening KP21 is smaller than the width WP22 of the fourth pixel sub-opening KP22.

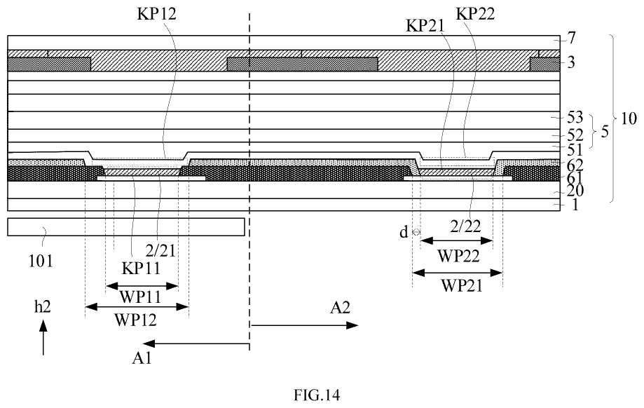

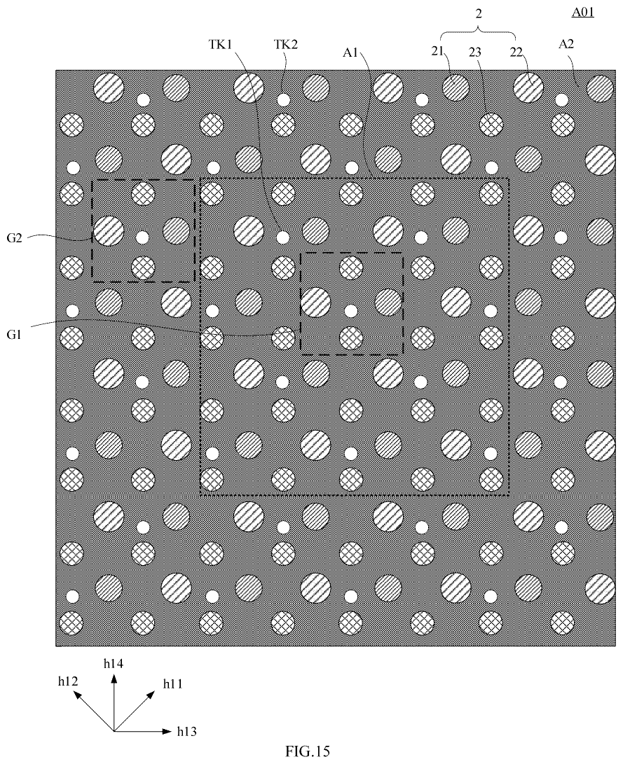

Alternatively, as shown in FIG. 14, which is a schematic cross-sectional view of a first display region and a second display region of yet another display module provided by an embodiment of the present disclosure, a width WP11 of the first pixel sub-opening KP11 is smaller than a width WP12 of the second pixel sub-opening KP12, a width WP21 of the third pixel sub-opening KP21 is greater than a width WP22 of the fourth pixel sub-opening KP22, and the width WP11 of the first pixel sub-opening KP11 is equal to the width WP22 of the fourth pixel sub-opening KP22. A width direction of the first pixel sub-opening KP11 is parallel to a width direction of the fourth pixel sub-opening KP22.

In an embodiment of the present disclosure, the light-emitting region where the light-emitting unit 2 is located in the first display region A1 is the region where the first pixel sub-opening KP11 is located, and the light-emitting region where the light-emitting unit 2 is located in the second display region A2 is the region where the fourth pixel sub-opening KP22 is located. In the embodiment of the present disclosure, by making the width of the first pixel sub-opening KP11 equal to the width of the fourth pixel sub-opening KP22, the area of the light emitting region where the light-emitting unit 2 is located in the first display region A1 may be the same as the area of the light emitting region where the light-emitting unit 2 is located in the second display region A2, so that the lifetime and the color shift degree of the light-emitting units 2 of the same color tend to be consistent, thereby improving the display uniformity of the first display region A1 and the second display region A2.

In addition, in the embodiment of the present disclosure, since the light transmittance of the first pixel definition layer 61 is lower, in the first display region A1 and the second display region A2, the reflection region in the light-emitting region is defined by the first pixel opening in the first pixel definition layer 61. That is, in the first display region A1, the reflection region in the light-emitting region is defined by the region where the first pixel sub-opening KP11 is located, and in the second display region A2, the reflection region in the light-emitting region is defined by the region where the third pixel sub-opening KP21 is located. The arrangement provided by the embodiment of the present invention, while achieving that the areas of the light-emitting regions of the light-emitting units 20 with the same light-emitting color in the first display region A1 and the second display region A2 are the same, can make the reflectance of the reflective region in the first display region A1 smaller than the reflectance of the reflective region in the second display region A2 by making the width of the first pixel sub-opening KP11 smaller than the width of the third pixel sub-opening KP21, which can compensate for the overall difference in reflectance between the second display region A2 and the first display region A1 caused by the provision of the light transmitting holes in the related art and improve the visual effect consistency of the display panel 10 in a screen-off state.

It should be noted that both the first display region A1 and the second display region A2 includes a plurality of light-emitting units 2 of different colors. Correspondingly, the first display region A1 and the second display region A2 include a plurality of pixel openings for accommodating the light-emitting units 2 of different colors. A width of the first pixel opening in the first display region A1 is equal to a width of the second pixel opening in the second display region A2, which means that for the pixel openings for accommodating light-emitting units 2 of the same color in the first display region A1 and the second display region A2, the width of the first pixel opening in the first display region A1 is equal to the width of the second pixel opening in the second display region A2. FIG. 14 illustrates the pixel openings for accommodating the first color light-emitting units in the first display region A1 and the second display region A2. The situations of the pixel openings for accommodating the second color light-emitting units and the third color light-emitting units are similar to this, and will not be described one by one here.

Exemplarily, as shown in FIG. 14, in the second display region A2, a distance d is provided between the third pixel sub-opening KP21 and the fourth pixel sub-opening KP22 along the direction parallel to the plane of the substrate 1, and in the embodiment of the present disclosure, the distance d can be adjusted to adjust the increment in reflectance of the opening region in the second display region A2, thereby reducing the difference in reflectance from the first display region A1.

Exemplarily, as shown in FIG. 14, in the second display region A2, along the direction parallel to the plane of the substrate 1, a distance d between the second pixel opening and the first pixel opening satisfies: 1 μm≤d≤5 μm. That is, the distance d between the third pixel sub-opening KP21 and the fourth pixel sub-opening KP22 satisfies: 1 μm≤d≤5 μm. Based on this arrangement, it can be avoided that the distance d between the third pixel sub-opening KP21 and the fourth pixel sub-opening KP22 is set too large, and in the case where the width of the third pixel sub-opening KP21 is determined and the reflectance is determined, it can be avoided that the width of the fourth pixel sub-opening KP22 is set too small, thereby ensuring that the area of the light-emitting region where the light-emitting unit 2 is located in the second display area A2 is not too small. Moreover, in the case where the width of the fourth pixel sub-opening KP22 is determined, it can be avoided that the width of the third pixel sub-opening KP21 is set too large, so that it is possible to avoid the reflectance of the second display region A2 from being too large, which is beneficial to ensuring the basic reflectance specification requirement of the second display region A2.

Exemplarily, as shown in FIG. 3, in the first display region A1, along the direction parallel to the plane of the substrate 1, a shortest distance between the first opening K1 and the light-emitting unit 2 is d1, and a width of the light-emitting unit 2 is W21. A width direction of the light-emitting unit 2 is parallel to the direction of the shortest distance between the first opening K1 and the light-emitting unit 2. A distance between a plane of the light-shielding layer 3 away from the substrate 1 and the light-emitting unit 2 in the direction perpendicular to the plane of the substrate 1 is H1.

In the second display region A2, along the direction parallel to the plane of the substrate 1, the shortest distance between the first opening K1 and the light-emitting unit 2 is d2, and the width of the light-emitting unit 2 is W22. The distance between the plane of the light-shielding layer 3 away from the substrate 1 and the light-emitting unit 2 in the direction perpendicular to the plane of the substrate 1 is H2, where (W21+d1)/H1=(W22+d2)/H2.

When the display panel 10 is in operation, the small-angle light emitted by the light-emitting unit 2 is emitted through the first opening K1, while the large-angle light is shielded by the non-opening position of the light-shielding layer 3 and thus cannot be emitted from the display panel 10. An included angle between a propagation direction of the small-angle light and the normal line of the plane of the substrate 1 is smaller than an included angle between a propagation direction of the large-angle light and the normal line of the plane of the substrate 1. In the embodiment of the present disclosure, by setting (W21+d1)/H1=(W22+d2)/H2, a maximum angle θ1 of the light emitted by the light-emitting unit in the first display region that can exit through the first opening K1 and a maximum angle θ2 of the light emitted by the light-emitting unit in the second display region that can exit through the first opening K1 satisfy: θ1=θ2, so that the color shift and lifetime of the light-emitting units 2 in the first display region A1 and the second display region A2 can tend to be consistent, which is conducive to improving the display uniformity between different regions of the display panel 10.

Exemplarily, the distance between the plane of the light-shielding layer 3 away from the substrate 1 and the light-emitting unit 2 in the direction perpendicular to the plane of the substrate 1 may be a distance between the plane of the light-shielding layer 3 away from the substrate 1 and the light-emitting layer 200 in the direction perpendicular to the plane of the substrate 1. In the embodiment of the present disclosure, it is possible to set H1=H2, d1=d2, and W21=W22.

Exemplarily, as shown in FIG. 3 and FIG. 6, the display panel 10 further includes a driving circuit layer 20. The driving circuit layer 20 includes transistors (not shown in FIG. 3 and FIG. 6) and metal traces (not shown in FIG. 3 and FIG. 6). Along the direction h2 perpendicular to the plane of the substrate 1, the first light transmitting hole TK1, the second light transmitting hole TK2, and the third light transmitting hole TK3 are at least partially non-overlapping with the metal traces and the transistors in the driving circuit layer 20, to avoid the metal traces and the transistors from shielding the incident ambient light and affecting the light transmittance of the regions where the respective light transmitting holes are located.

Optionally, the number of light transmitting holes per unit area in the second display region A2 is smaller than or equal to the number of light transmitting holes per unit area in the first display region A1. That is, a density of the second light transmitting holes TK2 is smaller than or equal to a density of the first light transmitting holes TK1. Based on this arrangement, it can be avoided that the reflectance of the second display region A2 is increased excessively, and while reducing the difference in reflectance between the first display region A1 and the second display region A2, it can be ensured that the basic display effect of the second display region A2 is not affected.

Exemplarily, in an embodiments of the present disclosure, simulation and verification have been performed on the reflectance of the first display region and the second display region in conjunction with a comparative example.

In the comparative example, the first display region A1 includes a plurality of light transmitting holes, the second display region A2 does not include light transmitting holes. Moreover, the reflectance r01 of the region where a single light transmitting hole is located in the first display region A1 is 32%. The total area proportion m01 of the plurality of light transmitting holes in the first display region A1 in the display panel is 1.8%. The reflectance r00 of the region without hole formation in the second display region A2 is 4.4%. Accordingly, the overall reflectance R01 of the first display region A1 satisfies: R01=r01×m01=32%×1.8%=0.58%, and in a region with an area equal to the area of the regions where the plurality of light transmitting holes are located in the first display region A1, the overall reflectance R02 of the second display region A2 satisfies: R02=r00×m01=4.4%×1.8%=0.08%. Therefore, in the comparative example, the overall difference in reflectance ΔR0 between the first display region A1 and the second display region A2 satisfies: ΔR0=R01-R02=0.5%.

In the embodiment of the present disclosure, the first display region A1 includes a plurality of first light transmitting holes, and the reflectance r11 of a region where a single first light transmitting hole is located is 32%; and the second display region A2 includes a plurality of second light transmitting holes, and the reflectance r12 of a region where a single second light transmitting hole is located is 26%. The total area proportion m11 of the plurality of first light transmitting holes in the first display region A1 in the display panel is 1.8%, and the total area proportion m12 of the plurality of second light transmitting holes in the second display region A2 in the display panel is 0.8%. Accordingly, the overall reflectance R11 of the first display region A1 satisfies: R11=r11×m11=32%×1.8%=0.58%, and in a region with an area equal to the area of the regions where the plurality of light transmitting holes are located in the first display region A1, the overall reflectance R12 of the second display region A2 satisfies: R12=r12×m12+r00×(m11−m12)=26%×0.8%+4.4%×1.0%=0.21%+0.04%=0.25%. Therefore, in the embodiment of the present disclosure, the overall difference in reflectance ΔR1 between the first display region A1 and the second display region A2 satisfies: ΔR1=R11−R12=0.33%<ΔR0.

It can be seen that by adopting the arrangement provided by this embodiment of the present disclosure, the overall difference in reflectance between the first display region A1 and the second display region A2 can be reduced, which is conducive to improving the visual effect consistency between the first display region A1 and the second display region A2 in a screen-off state.

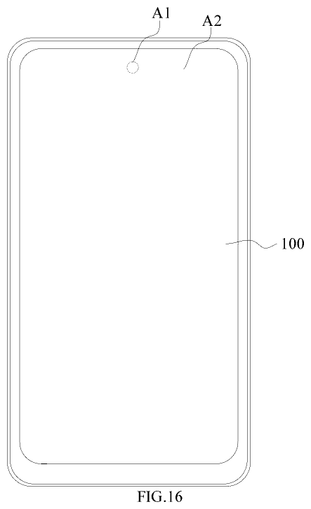

It should be noted that shapes and distribution positions of the first light transmitting holes TK1, the second light transmitting holes TK2, and the third light transmitting holes TK3 shown in FIG. 2 and FIG. 5 are merely illustrative, and are not limited in the embodiments of the present disclosure. For example, in the embodiments of the present disclosure, any one or more of the first light transmitting holes TK1, the second light transmitting holes TK2, and the third light transmitting holes TK3 may be shaped as circles, ellipses, or circular-like shapes similar to circles. As shown in FIG. 15, which is another enlarged schematic view of the region A01 in FIG. 1, the shapes of the first light transmitting holes TK1 and the second light transmitting holes TK2 are designed as circles.

When the first light transmitting holes TK1 are designed as circles, the diffraction phenomenon of the light from the external environment when passing through the first light transmitting holes TK1 can be suppressed, which is beneficial to improving the light intensity consistency of the ambient light passing through the first display region A1 at different positions, and thus improving the operating performance of the first optical sensor 101.

When the second light transmitting holes TK2 are designed as circles, the diffraction phenomenon of the light from the external environment when passing through the second light transmitting holes TK2 can be suppressed, which is beneficial to improving the visual consistency at different positions in the second display region A2.

When the third light transmitting holes TK3 are designed as circles, the diffraction phenomenon of the light from the external environment when passing through the third light transmitting holes TK3 can be suppressed, which is beneficial to improving the light intensity consistency of the ambient light passing through the third display region A3 at different positions, and thus improving the operating performance of the second optical sensor 102.

It should be further noted that the shapes of the first display region A1 and the second display region A2 shown in FIG. 1 and FIG. 4 and the shape of the third display region A3 shown in FIG. 4 are all illustrative, and in the embodiments of the disclosure, the shape of any one of the first display region A1, the second display region A2, and the third display region A3 may be designed as a circle, a polygon, or an irregular shape. This is not limited in the embodiments of the present disclosure. FIG. 1 illustrates that the shapes of the first display region A1 and the second display region A2 are both designed as quadrangles. FIG. 4 illustrates that the shape of the first display region A1 is designed as a circle, and the shapes of the second display region A2 and the third display region A3 are designed as quadrangles.

Based on the same inventive concept, an embodiment of the present disclosure further provides a display apparatus, as shown in FIG. 16, which is a schematic view of a display apparatus provided by an embodiment of the present disclosure. The display apparatus includes the above-mentioned display module 100. The specific structure of the display module 100 has been described in detail in the foregoing embodiments, and is not described herein again. Of course, the display apparatus shown in FIG. 16 is merely illustrative, and the display apparatus may be any apparatus having a display function, such as a mobile phone, a tablet computer, a notebook computer, an electronic paper book, a television, and a smart watch. This is not limited in the embodiments of the present disclosure.

The above are only preferred embodiments of the present disclosure and are not intended to limit the present disclosure, and any modifications, equivalent substitutions, improvements and the like made within the spirit and principle of the present disclosure should be included within the scope of protection of the present disclosure.

The same or similar parts among the various embodiments in this specification can be referred to each other. In particular, for the apparatus embodiments and terminal embodiments, since they are basically similar to the method embodiments, the description of them is relatively simple, and relevant details may be referred to the explanations in the method embodiments.

What is claimed is:

1. A display module comprising:
a display panel; and
a first optical sensor;
wherein the display panel comprises a first display region and a second display region, and a light transmittance of the first display region is greater than or equal to a light transmittance of the second display region; and
wherein both the first display region and the second display region comprise a substrate, light-emitting units, and light transmitting holes, and the light-emitting units and the light transmitting holes are located on a same side of the substrate; and along a direction perpendicular to a plane of the substrate, the first optical sensor at least partially overlaps with the first display region, the first optical sensor does not overlap with the second display region, and the light-emitting units do not overlap with the light transmitting holes.

2. The display module according to claim 1, wherein a density of the light-emitting units in the first display region is equal to a density of the light-emitting units in the second display region.

3. The display module according to claim 1, wherein the display panel further comprises a third display region, wherein the third display region comprises light-emitting units, and a density of the light-emitting units in the third display region is smaller than or equal to a density of the light-emitting units in the second display region.

4. The display module according to claim 3, further comprising a second optical sensor, wherein along the direction perpendicular to the plane of the substrate, the second optical sensor at least partially overlaps with the third display region.

5. The display module according to claim 1, wherein the display panel further comprises a light-shielding layer comprising first openings and second openings;
wherein along the direction perpendicular to the plane of the substrate, the light-emitting units at least partially overlap with the first openings; and
wherein at least one of the light transmitting holes in the second display region and the light transmitting holes in the first display region comprises the second openings.

6. The display module according to claim 1, wherein the display panel further comprises a color filter layer, and along the direction perpendicular to the plane of the substrate, the light-emitting units at least partially overlaps with the color filter layer;
wherein the color filter layer comprises third openings; and
wherein at least one of the light transmitting holes in the second display region and the light transmitting holes in the first display region comprises the third openings.

7. The display module according to claim 1, wherein the display panel further comprises a pixel definition layer comprising pixel openings, and at least some of the light-emitting units are located in the pixel openings;
wherein the pixel definition layer further comprises fourth openings; and
wherein at least one of the light transmitting holes in the second display region and the light transmitting holes in the first display region comprises the fourth openings.

8. The display module according to claim 1, wherein the display panel further comprises a first pixel definition layer and a second pixel definition layer that are stacked, and the first pixel definition layer is located on a side of the second pixel definition layer close to the substrate;
wherein a light transmittance of the first pixel definition layer is smaller than or equal to a light transmittance of the second pixel definition layer;
wherein the first pixel definition layer comprises first pixel openings, the second pixel definition layer comprises second pixel openings, and, along the direction perpendicular to the plane of the substrate, the first pixel openings at least partially overlap with the second pixel openings; and
wherein at least some of the light-emitting units are located in the first pixel openings and the second pixel openings.

9. The display module according to claim 8, wherein in the first display region, an area of at least one of the first pixel openings is smaller than an area of at least one of the second pixel openings, and an orthographic projection of the second pixel opening onto the plane of the substrate covers an orthographic projection of the first pixel opening onto the plane of the substrate; and
wherein in the second display region, an area of at least one of the first pixel openings is greater than an area of at least one of the second pixel openings, and an orthographic projection of the first pixel opening onto the plane of the substrate covers an orthographic projection of the second pixel opening onto the plane of the substrate.

10. The display module according to claim 8, wherein along a direction parallel to the plane of the substrate, a width of the first pixel opening in the first display region is equal to a width of the second pixel opening in the second display region, and a width direction of the first pixel opening is parallel to a width direction of the second pixel opening.

11. The display module according to claim 8, wherein in the second display region, along a direction parallel to the plane of the substrate, a distance d between the second pixel opening and the first pixel opening satisfies: 1 μm≤d≤5 μm.

12. The display module according to claim 1, wherein the display panel further comprises a pixel definition layer comprising pixel openings, and at least some of the light-emitting units are located in the pixel openings; and
wherein along a direction parallel to the plane of the substrate, a width of the pixel opening in the first display region is smaller than or equal to a width of the pixel opening in the second display region.

13. The display module according to claim 1, wherein the display panel further comprises a light-shielding layer comprising first openings; and along the direction perpendicular to the plane of the substrate, the light-emitting units at least partially overlaps with the first openings; and
wherein along a direction parallel to the plane of the substrate, a width of the first opening in the first display region is smaller than or equal to a width of the first opening in the second display region.

14. The display module according to claim 1, wherein the display panel further comprises a light-shielding layer comprising first openings; and along the direction perpendicular to the plane of the substrate, the light-emitting units at least partially overlaps with the first openings;
wherein along a direction parallel to the plane of the substrate, a shortest distance between the first opening in the first display region and the light-emitting unit is d1, a width of the light-emitting unit is W21, and a distance between a plane of the light-shielding layer away from the substrate and the light-emitting unit along the direction perpendicular to the plane of the substrate is H1;
wherein a shortest distance between the first opening in the second display region and the light-emitting unit is d2, a width of the light-emitting unit is W22, and a distance between the plane of the light-shielding layer away from the substrate and the light-emitting unit along the direction perpendicular to the plane of the substrate is H2; and
wherein (W21+d1)/H1=(W22+d2)/H2.

15. The display module according to claim 1, wherein the first display region comprises a first group, and the second display region comprises a second group; and
wherein after being translated, the light-emitting units and the light transmitting holes in the first group are respectively coincide with the light-emitting units and the light transmitting holes in the second group.

16. The display module according to claim 1, wherein an area of the light transmitting holes in the second display region is smaller than or equal to an area of the light transmitting holes in the first display region.

17. The display module according to claim 1, wherein a number of the light transmitting holes per unit area in the second display region is smaller than or equal to a number of the light transmitting holes per unit area in the first display region.

18. A display apparatus, comprising a display module, wherein the display module comprises a display panel and a first optical sensor;
wherein the display panel comprises a first display region and a second display region, and a light transmittance of the first display region is greater than or equal to a light transmittance of the second display region; and
wherein both the first display region and the second display region comprise a substrate, light-emitting units, and light transmitting holes, and the light-emitting units and light transmitting holes are located on a same side of the substrate; and along a direction perpendicular to a plane of the substrate, the first optical sensor at least partially overlaps with the first display region, the first optical sensor does not overlap with the second display region, and the light-emitting units do not overlap with the light transmitting holes.
